(19) United States
(12) Patent Application Publication
(10) Pub. No.: US 2025/0296832 A1
(43) Pub. Date: Sep. 25, 2025

(54) Electrostatic MEMS Transducer with Vertical Actuator Cells

(71) Applicant: Board of Regents, The University of Texas System, Austin, TX (US)

(72) Inventors: Siavash Pourkamali Anaraki, Allen, TX (US); Md Emran Hossain Bhuiyan, Dallas, TX (US); Prithviraj Palit, Dallas, TX (US)

(21) Appl. No.: 19/086,375

(22) Filed: Mar. 21, 2025

Related U.S. Application Data
(60) Provisional application No. 63/569,331, filed on Mar. 25, 2024.

(51) Int. Cl. B81B 3/00; B81C 1/00

(52) U.S. Cl. CPC B81B 3/0037; B81C 1/00682; B81B 2201/0257; B81B 2203/0127; B81B 2203/0307; B81B 2203/04; B81C 2201/0109; B81C 2201/0132; B81C 2201/0156; B81C 2201/0176

(57) ABSTRACT

An electrostatic MEMS transducer includes a membrane and an actuator array. The actuator array includes a plurality of vertical parallel-plate actuator cells. Each vertical actuator cell comprises two silicon electrodes and a polysilicon electrode positioned between the two silicon electrodes. The actuator cells are configured to generate oscillation of the membrane responsive to an electrical signal.

### CROSS-REFERENCE TO RELATED APPLICATION

This application claims priority to U.S. Provisional Application 63/569,331, filed Mar. 25, 2024, the entirety of which is hereby incorporated by reference in its entirely.

### STATEMENT OF GOVERNMENT INTEREST

This invention was made with government support under Grant No. 1923195 awarded by the National Science Foundation (NSF). The government has certain rights in the invention.

### BACKGROUND INFORMATION

### 1. Field

The present disclosure relates generally to micro-electromechanical systems (MEMS), and more specifically to electrostatic MEMS acoustic transducers with vertical actuator cells.

### 2. Background

Acoustic transducers, which convert electrical signals into audible or ultrasonic acoustic pressure waves, are used in various consumer electronics, including smartphones, laptops, headphones, wireless earbuds, and human-machine interfaces. The demand for miniaturized acoustic transducers, including speakers and micro-fans has grown significantly due to the need for compact device designs, cost-effective manufacturing, and improved integration with modern electronic circuits. While conventional technologies such as electric motors, moving coil and balanced armature systems have dominated the speaker and fan market, MEMS-based transducers are emerging as an alternative, offering advantages such as low power consumption, small form factors, and scalable batch fabrication.

Despite these advantages, existing MEMS acoustic transducer technologies face challenges in achieving high sound pressure level (SPL) and displacement efficiency due to their limited diaphragm displacement, which is constrained by the small size of transducers.

### SUMMARY

In an illustrative embodiment, an electrostatic MEMS transducer includes a membrane and an actuator array. The actuator array includes a plurality of vertical parallel-plate actuator cells. Each vertical actuator cell includes two silicon electrodes and a polysilicon electrode positioned between the two silicon electrodes. The actuator cells are configured to generate oscillation of the membrane responsive to an electrical signal.

In an illustrative embodiment, the electrostatic MEMS transducer includes dielectric layers on the silicon electrodes to provide electrical isolation between the silicon electrodes and polysilicon electrodes. The MEMS transducer also includes air gaps between the silicon electrodes and the polysilicon electrodes. The two silicon electrodes are mechanically coupled to the polysilicon electrode and movable relative to the polysilicon electrode.

In an illustrative embodiment, the polysilicon electrode includes a T-shaped structure having a vertical member and horizontal arms. The horizontal arms are mechanically coupled to the silicon electrodes.

In an illustrative embodiment, the silicon electrodes and polysilicon electrode are positioned parallel to each another.

In an illustrative embodiment, the applied electrical signal comprises a DC voltage and an AC voltage. The electrical signal causes displacement of the silicon electrodes resulting in altering the gap between the silicon electrodes and the polysilicon electrodes.

In an illustrative embodiment, an electrostatic MEMS transducer includes a membrane and an actuator array. The actuator array includes a plurality of vertical parallel-plate actuator cells. Each vertical actuator cell includes two silicon electrodes and a polysilicon electrode having a vertical member and horizontal arms. The horizontal arms are mechanically coupled to the silicon electrodes. The vertical actuator cell includes dielectric layers on the silicon electrodes to provide electrical isolation between the silicon electrodes and polysilicon electrodes. The actuator cells are configured to generate oscillation of the membrane responsive to an electrical signal.

In an illustrative embodiment, a method for fabricating actuator cells of an electrostatic MEMS transducer comprises: etching vertical trenches in a device layer of a silicon-on-insulator (SOI) substrate to define actuator areas, wherein the SOI substrate comprises a silicon handle layer, a buried oxide layer, and a device layer; performing thermal oxidation and oxide removal to smooth sidewalls of the vertical trenches; depositing a silicon nitride layer conformally on the sidewalls of the vertical trenches; depositing a silicon dioxide layer over the silicon nitride layer to serve as a sacrificial layer defining transduction air gaps; depositing a first polysilicon layer over the silicon dioxide layer; blanket-etching the first polysilicon layer to expose the underlying sacrificial layer; selectively removing portions of the sacrificial layer to define anchoring points for silicon electrodes; depositing a second polysilicon layer over the first polysilicon layer; patterning the second polysilicon layer to form interconnections between polysilicon electrodes and the anchor points; performing a topside lithography process to define an outline of the MEMS transducer; performing a backside lithography process followed by a deep reactive ion etch to selectively remove the silicon handle layer under the membrane and actuator cells.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 illustrates a schematic diagram of a MEMS transducer in accordance with an illustrative embodiment;

FIG. 2 illustrates cross-section view of section 120 of a MEMS transducer in accordance with an illustrative embodiment;

FIG. 3 illustrates a schematic representation of a silicon membrane and actuator array area positioned along its four edges in accordance with an illustrative embodiment;

FIG. 4A illustrates a cross-sectional view of a vertical actuator cell before an actuation voltage is applied in accordance with an illustrative embodiment;

FIG. 4B illustrates the actuator cell after the actuation voltage is applied in accordance with an illustrative embodiment;

FIG. 5 illustrates a perspective view of an actuator cell in accordance with an illustrative embodiment; and

FIGS. 6A-6I illustrate fabrication of actuator cells in accordance with an illustrative embodiment.

### DETAILED DESCRIPTION

Various aspects of the present disclosure are described by narrative text, schematics and block diagrams.

The present disclosure relates to electrostatic MEMS transducers, which include vertical actuators designed to improve sound pressure level (SPL) and displacement range while maintaining a compact and power-efficient design.

In the illustrative embodiments, a MEMS transducer comprises one or more membranes or diaphragms attached to a support structure. An array of vertical actuator cells are embedded in the membrane. Each vertical actuator cell includes conductive electrodes arranged as parallel-plate capacitors. In an example embodiment, each vertical actuator cell includes silicon electrodes and polysilicon electrodes arranged as parallel-plate capacitors. A submicron air gap separates the electrodes.

In the illustrative embodiments, the MEMS transducer operates based on the electrostatic actuation principle. The MEMS transducer generates sound by applying an electric field between electrodes, creating an electrostatic force that moves the membrane to produce sound waves. When a DC bias voltage is applied between the silicon and polysilicon electrodes, opposite charges accumulate, creating an attractive electrostatic force. This force pulls the electrodes together, altering the gap between them and modulating capacitance. When an AC signal (e.g., audio signal) is superimposed on the DC bias voltage, the electrostatic force varies with the changing voltage. This causes periodic movement of the silicon electrodes and the membrane, leading to vibrations that generate sound waves.

The present disclosure overcomes existing limitations by utilizing vertical electrostatic actuators with high-aspect-ratio capacitive gaps. This approach enhances actuation strength, allowing for greater membrane displacement and increased SPL while retaining the benefits of MEMS-based fabrication and integration.

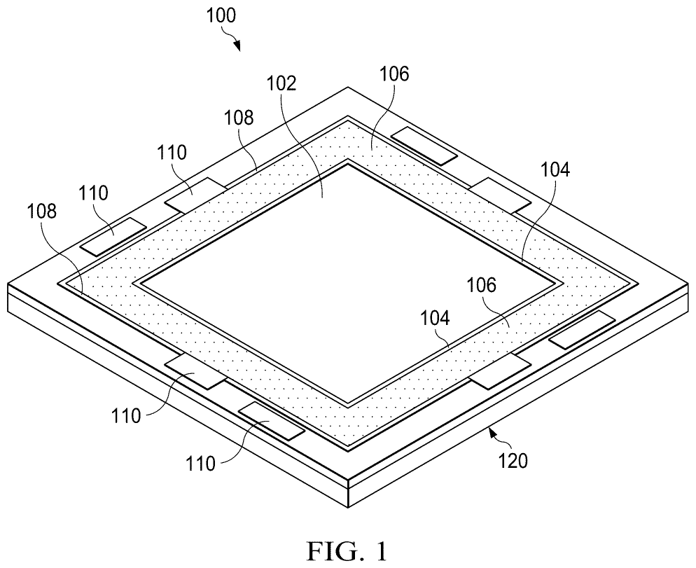

FIG. 1 illustrates a schematic diagram of MEMS transducer 100 in accordance with an illustrative embodiment. MEMS transducer 100 includes a silicon membrane 102 (e.g., diaphragm), which serves as the central vibrating structure. In the illustrative embodiment, silicon membrane 102 has a square shape; however, it may also take other forms, such as a rectangular shape. Silicon membrane 102 is attached to actuator array 106 along edges 104 of silicon membrane 102.

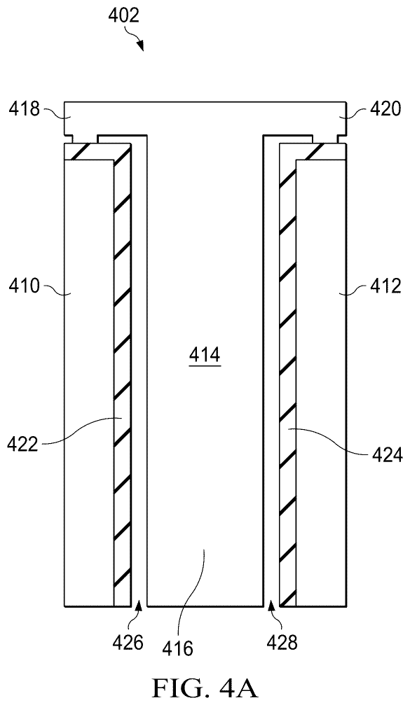

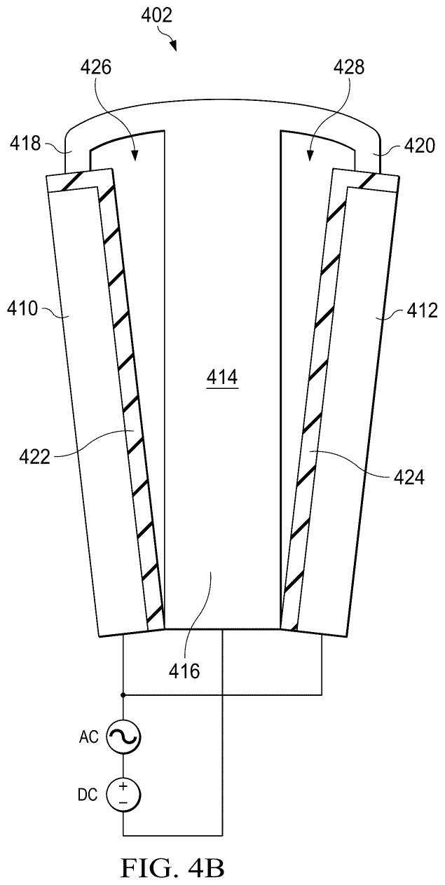

In some embodiments, silicon membrane 102 is a 50 micro-meters thick silicon substrate. MEMs speaker 100 includes actuator array 106 embedded along four edges of membrane 102. Actuator array 106 includes a plurality of vertical parallel plate actuator cells configured to generate oscillation of silicon membrane 102 responsive to an electrical signal. Actuator array 106 and the actuator cells are described with reference to FIGS. 4A and 4B.

In some embodiments, layer 108 facilitates the electrical connection between actuator array 106 and pads 110. Pads 110 serve as electrical interfaces, connecting the MEMS transducer to other components within the system.

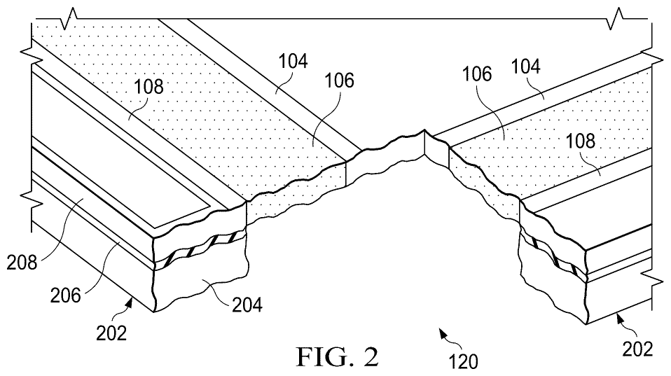

FIG. 2 illustrates cross-section view of section 120 of MEMS transducer 100. MEMs transducer 100 includes actuator array 106 embedded along edges 104 of the silicon membrane (not shown in FIG. 2). Actuator array 106 includes a plurality of vertical parallel plate actuator cells configured to generate oscillation of the silicon membrane responsive to an electrical signal. In some embodiments, layer 108 provides electrical connection between actuator array 106 and pads (not shown in FIG. 2). In some embodiments, layer 108 may be composed of polysilicon.

MEMS transducer 100 includes frame 202 along its edges. Frame 202 comprises handle layer 204, silicon device layer 208, and dielectric layer 206 between handle layer 204 and device layer 208. Frame 202 provides structural support and enhances the mechanical integrity of MEMS transducer 100.

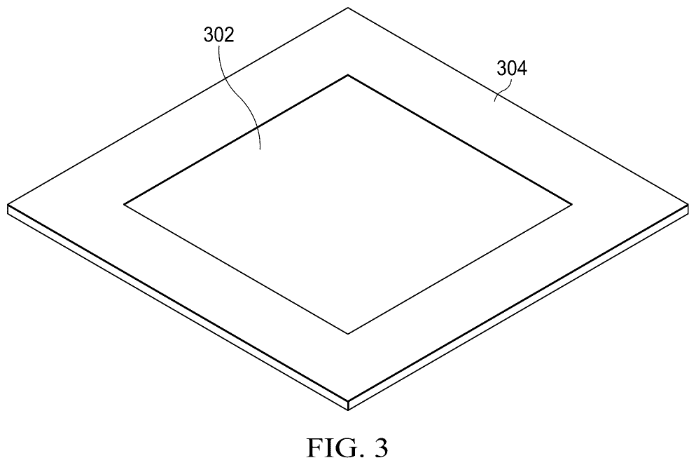

FIG. 3 illustrates a schematic representation of a silicon membrane 302 and actuator array area 304. Positioned along its four edges. Actuator array area 304 contains a plurality of embedded vertical parallel-plate actuator cells. In some embodiments, actuator array area 304 measures 4 mm×4 mm along the edges of silicon membrane 302. In some embodiments, actuator array 304 can be formed all across membrane 302. Thus, actuator array 204 may not be limited to the edges of silicon membrane 302 but may be formed all across the silicon membrane.

FIG. 4A illustrates a cross-sectional view of vertical actuator cell 402 before an actuation voltage is applied in accordance with an illustrative embodiment. Actuator cell 402 comprises two parallel plate electrodes, silicon electrodes 410 and 412, which function as one set of parallel-plate actuator electrodes. Polysilicon electrode 414 is positioned between silicon electrodes 410 and 412. Polysilicon electrode 414 functions as the counter electrode for the two parallel-plate actuators. In some embodiments, polysilicon electrode 414 has a T-shaped structure which has vertical member 416 and horizontal arms 418 and 420. Dielectric layers 422 and 424 are deposited on one side and the top of silicon electrodes 410 and 412 to provide electrical isolation from polysilicon electrode 414. Additionally, polysilicon electrode 414 is separated from silicon electrodes 410 and 412 by air gaps 426 and 428. In some embodiments, air gaps 426 and 428 are submicron transduction air gaps. Arms 418 and 420 are anchored (or mechanically coupled) to silicon electrodes 410 and 412.

Actuator cell 402 is designed with a high aspect ratio (tall and narrow structure), which maximizes the effective capacitive area while maintaining small gaps. Due to actuator cell 402's structure, which comprises parallel conductive plates (silicon electrodes 410 and 412 and polysilicon electrode 414) separated by air gaps 426 and 428, it operates as two parallel-plate capacitors, where charge accumulation occurs when a voltage is applied between silicon electrodes 410 and 412 and polysilicon electrode 414.

FIG. 4B illustrates actuator cell 402 after the actuation voltage is applied. When DC voltage VDC is applied between silicon electrodes 410 and 412 and polysilicon electrode 414, the resulting electrostatic force, generated by the attraction of opposite charges, causes the bottom sections of silicon electrodes 410 and 412 to move toward polysilicon electrode 414. This movement alters the gap between them at the bottom and, consequently, changes the capacitance. The degree of displacement depends on the applied voltage magnitude and the initial air gap size. Since the top sections of silicon electrodes 410 and 412 are anchored (or mechanically coupled) to polysilicon electrode 414, the movement of the bottom sections of electrodes 410 and 412 causes arms 418 and 420 of polysilicon electrode 414 to flex and bend downward.

When an AC voltage VAC is applied between silicon electrodes 410 and 412 and polysilicon electrode 414, the electrostatic force oscillates in response to the alternating voltage. This oscillating force causes periodic movement of the bottom sections of silicon electrodes 410 and 412, resulting in a dynamic displacement. As the actuator cells are positioned along the edges of silicon membrane 102 (shown in FIG. 1), their collective motion translates into vibrations of the entire membrane (shown in FIG. 1). These vibrations, in turn, generate sound waves, enabling MEMS transducer 100 to produce audible output.

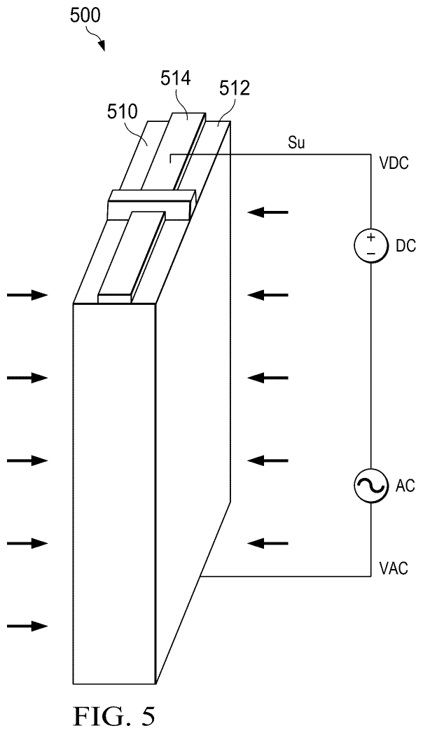

FIG. 5 illustrates a perspective view of actuator cell 500. Actuator cell 500 includes vertical silicon electrodes 510 and 512 positioned parallel to central polysilicon electrode 514, with submicron air gaps separating them.

When a DC voltage VDC is applied between silicon electrodes 510 and 512 and polysilicon electrode 514, opposite charges accumulate on the electrodes. This results in an electrostatic force (F) that pulls silicon electrodes 510 and 512 toward polysilicon electrode 514. Since the arms of the polysilicon electrode are anchored to the silicon electrodes on the top, locking them in place, the electrostatic force primarily affects the bottom portion of silicon electrodes 510 and 512, causing them to bend inward toward polysilicon electrode 514 (shown in FIGS. 4A and 4B). When an AC voltage VAC is applied, the electrostatic force oscillates, leading to periodic movement of silicon electrodes 510 and 512. This oscillatory motion translates into vibrations of the actuator array, which are transmitted to the silicon membrane, generating sound waves.

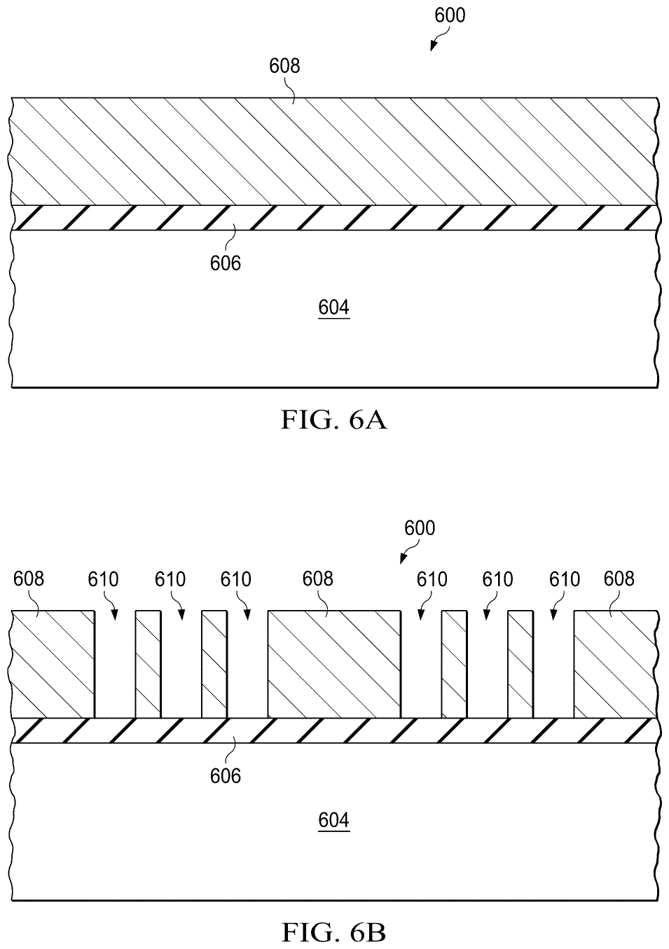

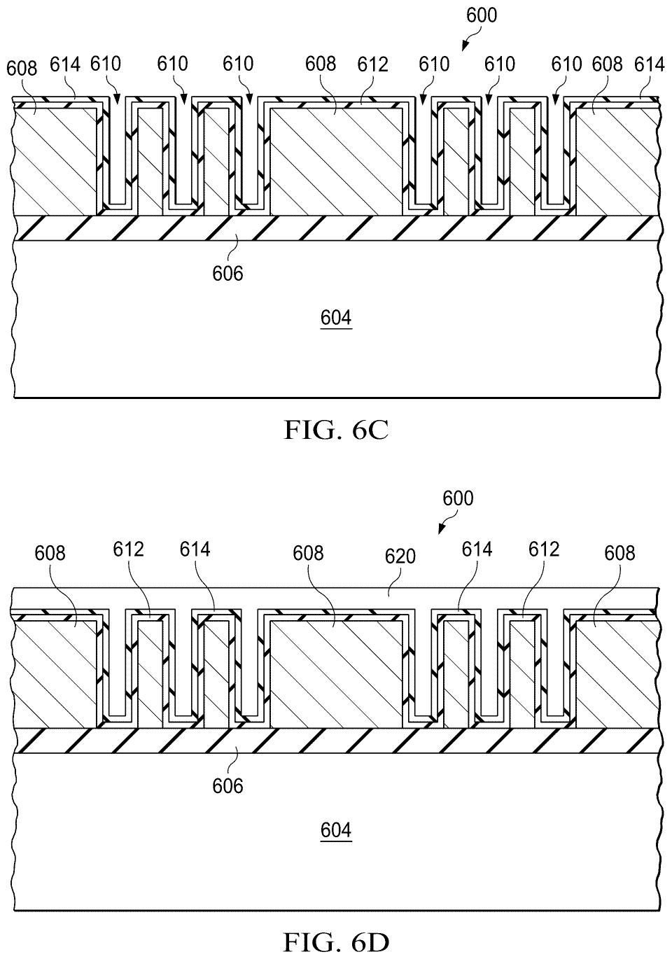

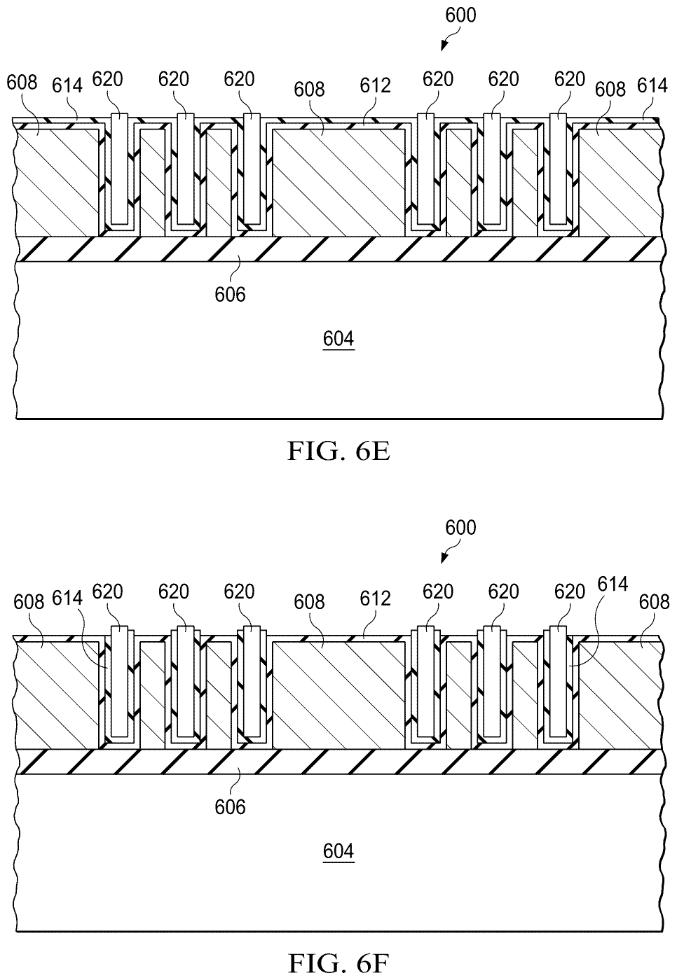

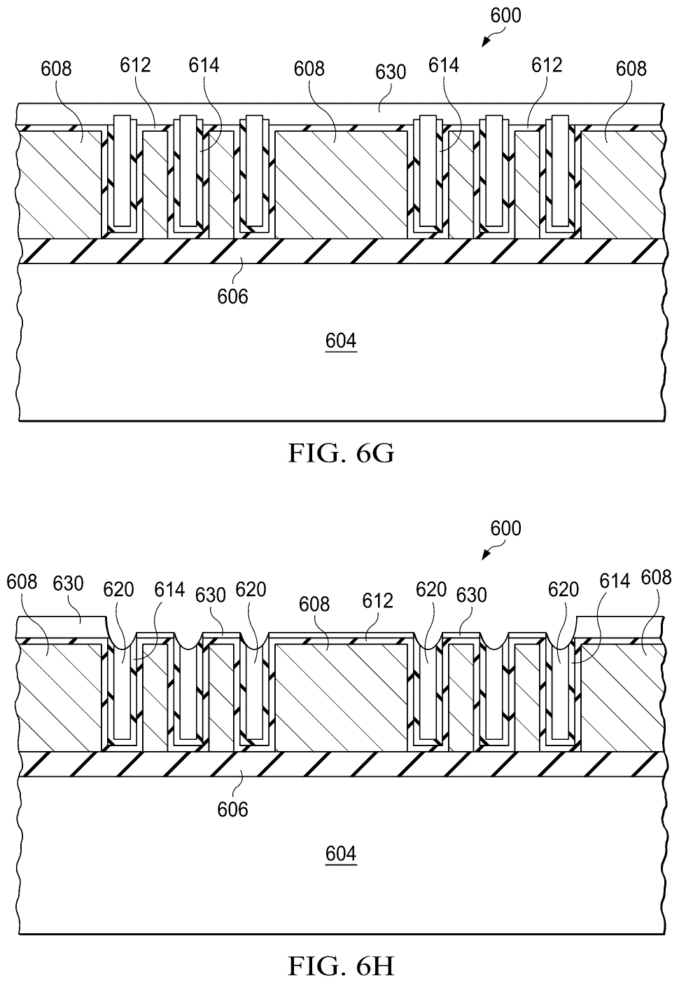

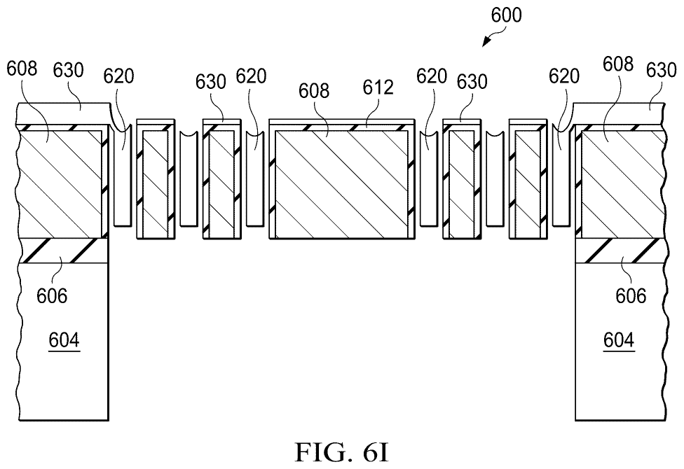

FIG. 6A-6I illustrate fabrication of actuator cells of a MEMS transducer utilizing a modified High Aspect Ratio Poly-Silicon (HARPSS) process in accordance with an illustrative embodiment. The process begins with forming silicon-on-insulator (SOI) substrate 600 (FIG. 6A) which includes silicon handle layer 604 over which buried oxide layer 606 is deposited. Device layer 608 is bonded over buried oxide layer 606 (e.g., 2 μm thick). In some embodiments, device layer 608 has a resistivity of 0.005 ohm/cm.

Next, actuator areas are defined by etching vertical trenches 610 into device layer 608 down to buried oxide layer 606 using Deep Reactive Ion Etching (DRIE) (FIG. 6B). A thermal oxidation and oxide removal step is performed to smooth out roughness in vertical trenches 610 caused by DRIE. In some embodiments, trenches 610 are not etched down to oxide layer 606.

Next, silicon nitride layer 612 (e.g., between 20 nm and 200 nm) is deposited, conformally covering the sidewalls of vertical trenches 610 (FIG. 6C), and silicon dioxide layer 614 (e.g., between 20 nm and 200 nm) is then deposited to act as a sacrificial layer, defining the transduction air gap between the silicon sidewalls and the polysilicon electrodes (FIG. 6C). In some embodiments, the silicon dioxide layer can be thermally grown.

Next, a 2-5 μm thick doped polysilicon layer 620 is deposited, covering silicon dioxide layer 614 (FIG. 6D). Next, polysilicon layer 620 is blanket-etched (FIG. 6E) to expose the sacrificial oxide underneath. A lithography process is used to selectively remove oxide film from areas where silicon electrodes will be anchored to the silicon device layer (FIG. 6F).

Next, a 0.5-3 μm thick second doped polysilicon layer 630 is deposited using LPCVD (Low Pressure Chemical Vapor Deposition) (FIG. 6G). In some embodiments, polysilicon layer 630 is annealed at 1100° C., improving its conductivity.

Next, a lithography process is used to pattern the second polysilicon layer, forming interconnections between the polysilicon electrodes and anchor points (FIG. 6H). Another topside lithography step is performed to define the final outline of the MEMS speaker.

A backside lithography process is followed by a deep DRIE etch to remove silicon handle layer 604 of the SOI substrate (FIG. 6I). A final step involves removing the sacrificial silicon dioxide using hydrofluoric acid (HF) (FIG. 6I).

As used herein, a first component “connected to” a second component means that the first component can be connected directly or indirectly to the second component. In other words, additional components may be present between the first component and the second component. The first component is considered to be indirectly connected to the second component when one or more additional components are present between the two components. When the first component is directly connected to the second component, no additional components are present between the two components.

As used herein, the phrase “a number” means one or more. The phrase “at least one of”, when used with a list of items, means different combinations of one or more of the listed items may be used, and only one of each item in the list may be needed. In other words, “at least one of” means any combination of items and number of items may be used from the list, but not all of the items in the list are required. The item may be a particular object, a thing, or a category.

For example, without limitation, “at least one of item A, item B, or item C” may include item A, item A and item B, or item C. This example also may include item A, item B, and item C or item B and item C. Of course, any combinations of these items may be present. In some illustrative examples, “at least one of” may be, for example, without limitation, two of item A; one of item B; and ten of item C; four of item B and seven of item C; or other suitable combinations.

The block diagrams in the different depicted embodiments illustrate the architecture, functionality, and operation of some possible implementations of apparatuses and methods in an illustrative embodiment. In this regard, each block in the block diagrams may represent at least one of a module, a segment, a function, or a portion of an operation or step. For example, one or more of the blocks may be implemented as program code.

In some alternative implementations of an illustrative embodiment, the function or functions noted in the blocks may occur out of the order noted in the figures. For example, in some cases, two blocks shown in succession may be performed substantially concurrently, or the blocks may sometimes be performed in the reverse order, depending upon the functionality involved. Also, other blocks may be added in addition to the illustrated blocks in a flowchart or block diagram.

The description of the different illustrative embodiments has been presented for purposes of illustration and description and is not intended to be exhaustive or limited to the embodiments in the form disclosed. Many modifications and variations will be apparent to those of ordinary skill in the art. Further, different illustrative embodiments may provide different features as compared to other illustrative embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

What is claimed is:

1. An electrostatic MEMS transducer comprising:
a membrane; and
an actuator array,
wherein the actuator array includes a plurality of vertical parallel-plate actuator cells, and wherein each vertical actuator cell comprises two silicon electrodes and a polysilicon electrode positioned between the two silicon electrodes, and wherein the actuator cells are configured to generate oscillation of the membrane responsive to an electrical signal.

2. The electrostatic MEMS transducer of claim 1, further comprising dielectric layers on the silicon electrodes to provide electrical isolation between the silicon electrodes and polysilicon electrodes.

3. The electrostatic MEMS transducer claim 1, further comprising air gaps between the silicon electrodes and the polysilicon electrodes.

4. The electrostatic MEMS transducer of claim 1, wherein the two silicon electrodes are mechanically coupled to the polysilicon electrode and movable relative to the polysilicon electrode.

5. The electrostatic MEMS transducer of claim 1, wherein the polysilicon electrode includes a T-shaped structure having a vertical member and horizontal arms, wherein the horizontal arms are mechanically coupled to the silicon electrodes.

6. The electrostatic MEMS transducer of claim 1, wherein the membrane is made from a silicon substrate.

7. The MEMS electrostatic transducer of claim 1, wherein the silicon electrodes and polysilicon electrode are positioned parallel to each another.

8. The MEMs electrostatic transducer of claim 1, wherein the dielectric layers are formed by silicon nitride.

9. The electrostatic MEMS transducer of claim 1, wherein the applied electrical signal comprises a DC voltage and an AC voltage.

10. The electrostatic MEMS transducer of claim 1, wherein the actuator cells are configured to operate as parallel-plate capacitors.

11. The electrostatic MEMS transducer of claim 1, wherein the electrical signal causes displacement of the silicon electrodes resulting in altering the gap between the silicon electrodes and the polysilicon electrodes.

12. An electrostatic MEMS transducer comprising:
a membrane; and
an actuator array,
wherein the actuator array includes a plurality of vertical parallel-plate actuator cells, and wherein each vertical actuator cell comprises:
two silicon electrodes;
a polysilicon electrode having a vertical member and horizontal arms, wherein the horizontal arms are mechanically coupled to the silicon electrodes; and
dielectric layers on the silicon electrodes to provide electrical isolation between the silicon electrodes and polysilicon electrodes,
wherein the silicon electrodes and the polysilicon electrode are electrically isolated from each other, and wherein the actuator cells are configured to generate oscillation of the membrane responsive to an electrical signal.

13. The electrostatic MEMS transducer of claim 12, wherein the two silicon electrodes are movable relative to the polysilicon electrode.

14. The electrostatic MEMS transducer of claim 12, wherein the applied electrical signal comprises a DC voltage and an AC voltage.

15. The electrostatic MEMS transducer of claim 12, further comprising submicron air gaps between the silicon electrodes and polysilicon electrode.

16. The electrostatic MEMs transducer of claim 12, wherein the silicon electrodes and polysilicon electrode are positioned parallel to one another.

17. The electrostatic MEMS transducer of claim 12, wherein the actuator cells are configured to operate as parallel-plate capacitors.

18. A method for fabricating actuator cells of an electrostatic MEMS transducer, comprising:
etching vertical trenches in a device layer of a silicon-on-insulator (SOI) substrate to define actuator areas, wherein the SOI substrate comprises a silicon handle layer, a buried oxide layer, and a device layer;
performing thermal oxidation and oxide removal to smooth sidewalls of the vertical trenches;
depositing a silicon nitride layer conformally on the sidewalls of the vertical trenches;
depositing a silicon dioxide layer over the silicon nitride layer to serve as a sacrificial layer defining transduction air gaps;
depositing a first polysilicon layer over the silicon dioxide layer;
blanket-etching the first polysilicon layer to expose the underlying sacrificial layer;
selectively removing portions of the sacrificial layer to define anchoring points for silicon electrodes;
depositing a second polysilicon layer over the first polysilicon layer;
patterning the second polysilicon layer to form interconnections between polysilicon electrodes and the anchor points;
performing a topside lithography process to define an outline of the MEMS transducer; and
performing a backside lithography process followed by a deep reactive ion etch to selectively remove the silicon handle layer under the membrane and actuator cells.

19. The method of claim 18, further comprising etching the vertical trenches in the device layer down to the buried oxide layer by deep reactive ion etching (DRIE).

20. The method of claim 18, further comprising removing the sacrificial silicon dioxide layer using hydrofluoric acid (HF).
